(19) United States
(12) Patent Application Publication
(10) Pub. No.: US 2025/0239631 A1
(43) Pub. Date: Jul. 24, 2025

(54) FUEL CELL APPARATUS

(71) Applicants: Hyundai Motor Company, Seoul (KR); Kia Corporation, Seoul (KR)

(72) Inventor: Dae Han KA, Yongin-Si (KR)

(73) Assignees: Hyundai Motor Company, Seoul (KR); Kia Corporation, Seoul (KR)

(21) Appl. No.: 18/812,718

(22) Filed: Aug. 22, 2024

(30) Foreign Application Priority Data
Jan. 23, 2024 (KR) 10-2024-0010196

(51) Int. Cl. H01M 8/0256; H01M 8/0239

(52) U.S. Cl. CPC H01M 8/0256; H01M 8/0239; H01M 2250/20

(57) ABSTRACT

A fuel cell apparatus includes a fuel cell including a cell stack including a plurality of unit cells stacked in a first direction and a cell monitoring connector mounted to the fuel cell in a second direction intersecting the first direction. The fuel cell includes a plurality of separators included in each of the unit cells and spaced from each other in the first direction, and each of the separators include an external side surface in which a female-type connection portion is concavely formed. The cell monitoring connector includes a housing and a male-type connection portion convexly protruding from the housing to mate with the female-type connection portion and to make surface-contact with the external side surface of each of the separators within the female-type connection portion.

### CROSS-REFERENCE TO RELATED APPLICATION

The present application claims priority to Korean Patent Application No. 10-2024-0010196, filed on Jan. 23, 2024, the entire contents of which is incorporated herein for all purposes by this reference.

### BACKGROUND OF THE PRESENT DISCLOSURE

### Field of the Present Disclosure

The present disclosure relates to a fuel cell apparatus.

### Description of Related Art

A cell stack of a fuel cell may supply power, generated through electrochemical reaction between air supplied to one surface of a polymer electrolyte membrane and hydrogen supplied to the opposite surface of the polymer electrolyte membrane, to an external load.

A cell stack may have a structure in which hundreds of unit cells are stacked. When the unit cells operate normally during operation of the cell stack, the unit cells may form a predetermined magnitude of voltage. In the instant case, if any one of hundreds of cells fails to exhibit normal performance, the total output of the cell stack is lowered. If this reverse voltage phenomenon continues, operation of the cell stack needs to be stopped.

A cell monitoring connector of a fuel cell apparatus checks the state of each of unit cells and continuously monitors the voltage of each of the unit cells. To this end, the cell monitoring connector may electrically contact with the cells to check the voltage of each of the unit cells forming the cell stack. Studies regarding various structures for electrical connection between the cell monitoring connector and the cell stack are underway.

The information disclosed in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a fuel cell apparatus that substantially obviates one or more problems due to limitations and disadvantages of the related art.

Embodiments provide a fuel cell apparatus in which a fuel cell and a cell monitoring connector are easily and rapidly assembled to each other.

However, the objects to be accomplished by the exemplary embodiments are not limited to the above-mentioned objects, and other objects not mentioned herein will be clearly understood by those skilled in the art from the following description.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

According to an exemplary embodiment of the present disclosure, a fuel cell apparatus may include a fuel cell including a cell stack including a plurality of unit cells stacked in a first direction and a cell monitoring connector mounted to the fuel cell in a second direction intersecting the first direction. The fuel cell may include a plurality of separators included in each of the unit cells and spaced from each other in the first direction, and each of the separators may include an external side surface in which a first connection portion is concavely formed. The cell monitoring connector may include a housing and a second connection portion convexly protruding from the housing to mate with the first connection portion and to make surface-contact with the external side surface of each of the separators within the first connection portion.

In an exemplary embodiment of the present disclosure, the second connection portion may be locked in a state of being fitted to the first connection portion by the spring force of the second connection portion.

In an exemplary embodiment of the present disclosure, the housing may include a front surface on which the second connection portion is disposed and a rear surface formed opposite to the front surface in the second direction, and the fuel cell may further include end plates disposed at respective end portions of the cell stack.

In an exemplary embodiment of the present disclosure, the fuel cell apparatus may further include a fixing frame disposed on the rear surface of the housing and supporting the housing, and the fixing frame may include a support portion disposed on the rear surface of the housing and coupling portions formed at first and second end portions of the support portion in the first direction to be coupled to the end plates.

In an exemplary embodiment of the present disclosure, the fuel cell apparatus may further include a control circuit connected to the cell monitoring connector, and the control circuit may be disposed between the rear surface of the housing and the fixing frame.

In an exemplary embodiment of the present disclosure, each of the unit cells may include a membrane electrode assembly, and the membrane electrode assembly may include a reaction surface disposed at the center portion thereof and a sub-gasket disposed around the reaction surface.

In an exemplary embodiment of the present disclosure, the sub-gasket may be disposed between first and second separators adjacent to each other among the plurality of separators, and the second connection portion may include one and another second connection portions formed to make surface-contact with the first and second separators, respectively. The sub-gasket may include a first portion disposed between the first and second separators while being spaced from the first and second separators in the first direction and a second portion extending from the first portion in the second direction and disposed between the one and another second connection portions while being spaced from the one and another second connection portions in the first direction.

In an exemplary embodiment of the present disclosure, the sub-gasket may include a film-type insulating material.

In an exemplary embodiment of the present disclosure, the sub-gasket may include a PEN film.

In an exemplary embodiment of the present disclosure, the external side surface of each of the separators making surface-contact with the second connection portion may have a first thickness in the first direction, and the second connection portion making surface-contact with the external side surface of each of the separators may have a second thickness in the first direction.

In an exemplary embodiment of the present disclosure, a portion at which the external side surface having the first thickness and the second connection portion having the second thickness overlap each other in the second direction may have an overlapping thickness in the first direction, and the overlapping thickness may be greater than or equal to half the first or second thickness.

In an exemplary embodiment of the present disclosure, the external side surface within the first connection portion of each of the separators making surface-contact with the second connection portion may have a uniform thickness, and the second connection portion making surface-contact with the external side surface of each of the separators may have a uniform thickness.

In an exemplary embodiment of the present disclosure, the first connection portion may have a V-shape, a rectangular shape, or an arc shape.

In an exemplary embodiment of the present disclosure, the second connection portion and each of the separators may not overlap each other in the first direction.

It is to be understood that the that the foregoing general description and the following detailed description of the present disclosure are exemplary and explanatory and are intended to provide further explanation of the present disclosure as claimed.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a cross-sectional view of end plates and a cell stack of a fuel cell;

FIG. 2 is an overall exploded perspective view of separators and a cell monitoring connector according to an exemplary embodiment of the present disclosure;

FIG. 3 is a partially exploded perspective view of the separators and the cell monitoring connector according to the embodiment;

FIG. 4A and FIG. 4B are, respectively, a partially coupled front view and an exploded front view of the separators and the cell monitoring connector shown in FIG. 3;

FIG. 5A and FIG. 5B are, respectively, a coupled cross-sectional view and an exploded cross-sectional view taken along line A-A′ in FIG. 4A;

FIG. 6A, FIG. 6B, and FIG. 6C are views showing exemplary shapes of a female-type connection portion and a male-type connection portion;

FIG. 7A is a front view of an exemplary embodiment of a membrane electrode assembly;

FIG. 7B is a front view of an exemplary embodiment of a separator;

FIG. 8A is an exploded perspective view of a fuel cell apparatus according to another exemplary embodiment of the present disclosure; and

FIG. 8B is a coupled perspective view of the fuel cell apparatus shown in FIG. 8A.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The present disclosure will now be described more fully hereinafter with reference to the accompanying drawings, in which various exemplary embodiments of the present disclosure are shown. The examples, however, may be embodied in various forms, and should not be construed as being limited to the exemplary embodiments set forth herein. Rather, these embodiments are provided so that the present disclosure will be more thorough and complete, and will more fully convey the scope of the present disclosure to those skilled in the art.

It will be understood that when an element is referred to as being “on” or “under” another element, it may be directly on/under the element, or one or more intervening elements may also be present.

When an element is referred to as being “on” or “under”, “under the element” as well as “on the element” may be included based on the element.

Furthermore, relational terms, such as “first”, “second”, “on/upper part/above”, and “under/lower part/below”, are used only to distinguish between one subject or element and another subject or element, without necessarily requiring or involving any physical or logical relationship or sequence between the subjects or elements.

Hereinafter, a fuel cell apparatus according to an exemplary embodiment will be described with reference to the accompanying drawings. The fuel cell apparatus will be described using the Cartesian coordinate system (x-axis, y-axis, z-axis) for convenience of description, but may also be described using other coordinate systems. In the Cartesian coordinate system, the x-axis, the y-axis, and the z-axis are perpendicular to each other, but the exemplary embodiments are not limited thereto. That is, the x-axis, the y-axis, and the z-axis may intersect each other obliquely. In the following description, the x-axis direction will be referred to as a “first direction”, the y-axis direction will be referred to as a “second direction”, and the z-axis direction will be referred to as a “third direction” for convenience of description. The first, second, and third directions may be perpendicular to each other or may intersect each other obliquely.

A fuel cell apparatus according to various exemplary embodiments of the present disclosure may include a fuel cell and a cell monitoring connector.

The fuel cell, to which the cell monitoring connector is mounted and connected, may be, for example, a polymer electrolyte membrane fuel cell (or proton exchange membrane fuel cell) (PEMFC), which has been studied most extensively as a power source for driving vehicles. However, the exemplary embodiments are not limited to any specific type of fuel cell.

The fuel cell may include end plates (pressing plates or compression plates) and a cell stack.

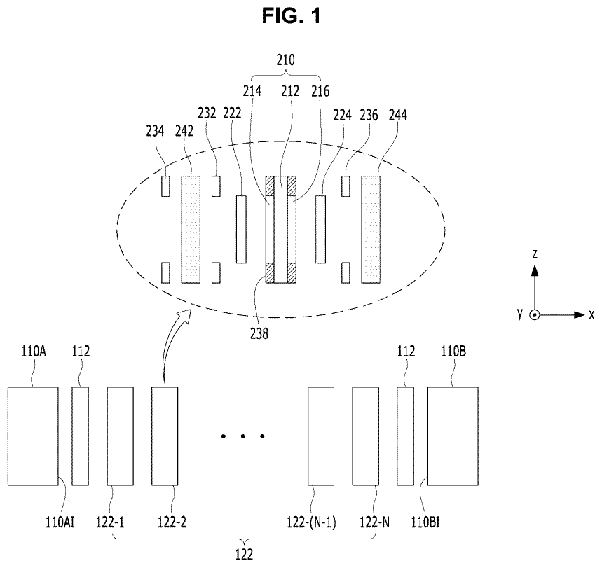

Hereinafter, an example of the cell stack will be described with reference to FIG. 1. However, the exemplary embodiments are not limited to any specific type of cell stack.

FIG. 1 is a cross-sectional view of end plates and a cell stack of a fuel cell.

A cell stack 122 may include a plurality of unit cells 122-1 to 122-N, which are stacked in the first direction. Here, “N” is a positive integer of 1 or greater, and may range from several tens to several hundreds. However, the exemplary embodiments are not limited to any specific value of “N”.

Each unit cell 122-n may generate electric power having a predetermined voltage. Here, 1≤n≤N. “N” may be determined depending on the intensity of the power to be supplied from the fuel cell to a load. Here, the load refers to a part of a vehicle that requires power when the fuel cell apparatus is used in the vehicle.

Each unit cell 122-n may include a membrane electrode assembly (MEA) 210, gas diffusion layers (GDLs) 222 and 224, gaskets 232, 234, and 236, and separators (or bipolar plates) 242 and 244.

The membrane electrode assembly 210 includes a structure in which catalyst electrode layers, in which electrochemical reaction occurs, are attached to both sides of an electrolyte membrane through which hydrogen ions move. The membrane electrode assembly 210 may include a polymer electrolyte membrane (or a proton exchange membrane) 212, a fuel electrode (a hydrogen electrode or an anode) 214, and an air electrode (an oxygen electrode or a cathode) 216. Furthermore, the membrane electrode assembly 210 may further include a sub-gasket 238.

The polymer electrolyte membrane 212 is disposed between the fuel electrode 214 and the air electrode 216.

Hydrogen, which is fuel in the fuel cell, may be supplied to the fuel electrode 214 through the first separator 242, and air containing oxygen as an oxidizer may be supplied to the air electrode 216 through the second separator 244.

The hydrogen supplied to the fuel electrode 214 is decomposed into hydrogen ions (protons) (H+) and electrons (e−) by the catalyst. Only the hydrogen ions may be selectively transferred to the air electrode 216 through the polymer electrolyte membrane 212, and at the same time, the electrons may be transferred to the air electrode 216 through the separators 242 and 244, which are conductors. To realize the above operation, a catalyst layer may be applied to each of the fuel electrode 214 and the air electrode 216. The movement of the electrons described above causes the electrons to flow through an external wire, thus generating current. That is, the fuel cell may generate power due to the electrochemical reaction between hydrogen, which is fuel, and oxygen contained in the air.

In the air electrode 216, the hydrogen ions supplied through the polymer electrolyte membrane 212 and the electrons transferred through the separators 242 and 244 meet oxygen in the air supplied to the air electrode 216, thus causing a reaction that generates water (“condensed water” or “product water”).

In some cases, the fuel electrode 214 may be referred to as an anode, and the air electrode 216 may be referred to as a cathode. Alternatively, the fuel electrode 214 may be referred to as a cathode, and the air electrode 216 may be referred to as an anode.

The gas diffusion layers 222 and 224 are configured to uniformly distribute hydrogen and oxygen, which are reactant gases, and to transfer the generated electrical energy. To the present end, the gas diffusion layers 222 and 224 may be disposed on respective sides of the membrane electrode assembly 210. That is, the first gas diffusion layer 222 may be disposed on the left side of the fuel electrode 214, and the second gas diffusion layer 224 may be disposed on the right side of the air electrode 216.

The first gas diffusion layer 222 is configured to diffuse and uniformly distribute hydrogen supplied as a reactant gas through the first separator 242, and may be electrically conductive. The second gas diffusion layer 224 is configured to diffuse and uniformly distribute air supplied as a reactant gas through the second separator 244, and may be electrically conductive.

Each of the first and second gas diffusion layers 222 and 224 may be a microporous layer in which fine carbon fibers are combined. However, the exemplary embodiments are not limited to any specific configuration of the first and second gas diffusion layers 222 and 224.

The gaskets 232, 234, and 236 are configured to maintain airtightness and for clamping pressure of the cell stack at an appropriate level with respect to the reactant gases and the coolant, to disperse the stress when the separators 242 and 244 are stacked, and to independently seal the flow paths. Accordingly, because airtightness and watertightness are maintained by the gaskets 232, 234, and 236, the flatness of the surfaces that are adjacent to the cell stack 122, which generates power, may be secured, and thus surface pressure may be distributed uniformly over the reaction surface of the cell stack 122. To the present end, the gaskets 232, 234, and 236 may be formed of rubber. However, the exemplary embodiments are not limited to any specific material of the gaskets.

The separators 242 and 244 is configured to move the reactant gases and the cooling medium and to separate each of the unit cells from the other unit cells. Furthermore, the separators 242 and 244 are configured to structurally support the membrane electrode assembly 210 and the gas diffusion layers 222 and 224 and to collect the generated current and transfer the collected current to current collectors 112.

The separators 242 and 244 may be disposed outside the gas diffusion layers 222 and 224, respectively. That is, the first separator 242 may be disposed on the left side of the first gas diffusion layer 222, and the second separator 244 may be disposed on the right side of the second gas diffusion layer 224.

The first separator 242 is configured to supply hydrogen as a reactant gas to the fuel electrode 214 through the first gas diffusion layer 222. The second separator 244 is configured to supply air as a reactant gas to the air electrode 216 through the second gas diffusion layer 224. Furthermore, each of the separators 242 and 244 may form a channel through which a cooling medium (e.g., coolant) may flow. Furthermore, the separators 242 and 244 may be formed of a graphite-based material, a composite graphite-based material, or a metal-based material. However, the exemplary embodiments are not limited to any specific material of the separators 242 and 244.

The end plates 110A and 110B shown in FIG. 1 may be disposed at the respective end portions of the cell stack 122, and may support and fix the unit cells 122. That is, the first end plate 110A may be disposed at one end portion of the cell stack 122, and the second end plate 110B may be disposed at the opposite end portion of the cell stack 122.

Each of the end plates 110A and 110B may be configured so that a metal insert is surrounded by a plastic injection-molded product. The metal insert of each of the end plates 110A and 110B may have high rigidity to withstand internal surface pressure, and may be formed by machining a metal material. For example, each of the end plates 110A and 110B may be formed by combining a plurality of plates. However, the exemplary embodiments are not limited to any specific configuration of the end plates 110A and 110B.

The current collectors 112 may be disposed between the cell stack 122 and the internal surfaces 110AI and 110BI of the end plates 110A and 110B that face the cell stack 122. The current collectors 112 are configured to collect the electrical energy generated by the flow of electrons in the cell stack 122 and to supply the electrical energy to a load that utilizes the fuel cell.

Furthermore, the first end plate 110A may include a plurality of manifolds (or communicating portions) M. Here, the manifolds may include an inlet manifold and an outlet manifold. Hydrogen and oxygen, which are reactant gases necessary in the membrane electrode assembly 210, may be introduced from the outside thereof into the cell stack 122 through the inlet manifold. Gas or liquid, in which the reactant gases humidified and supplied to the cell and the condensed water generated in the cell are combined, may be discharged to the outside of the fuel cell through the outlet manifold. The cooling medium may flow from the outside thereof into the cell stack 122 through the inlet manifold and may flow from the cell stack 122 to the outside through the outlet manifold. As described above, the manifolds allow the fluid to flow in and out of the membrane electrode assembly 210.

Meanwhile, to determine the performance of the cell stack 122 and whether the cell stack 122 operates normally or abnormally, the separators 242 and 244 of each cell may be connected to a control circuit via a fuel cell monitoring connector (or fuel stack voltage monitor (FSVM)) and wires. In the present way, the voltage of each cell may be measured.

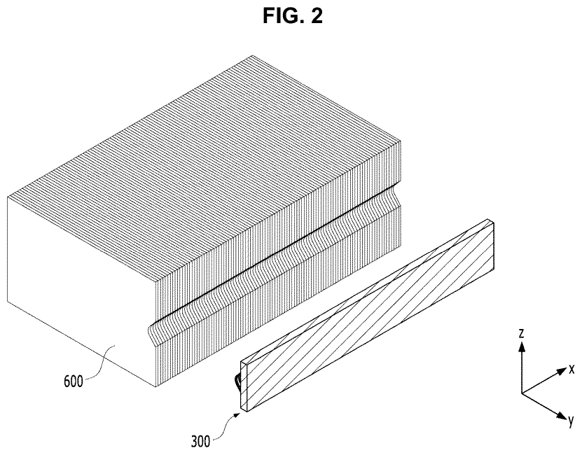

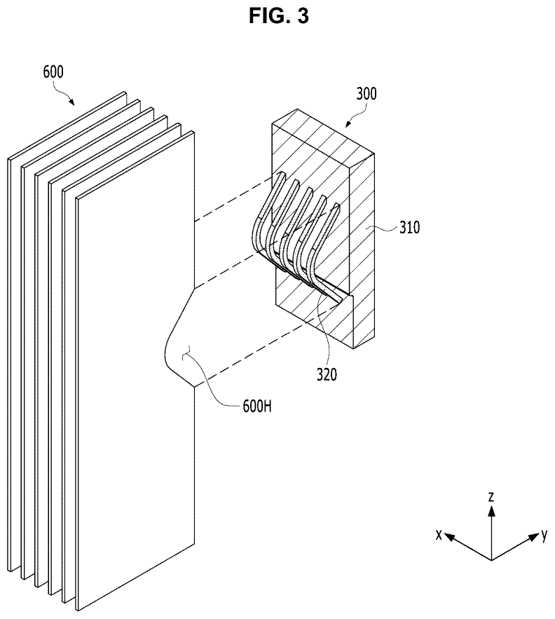

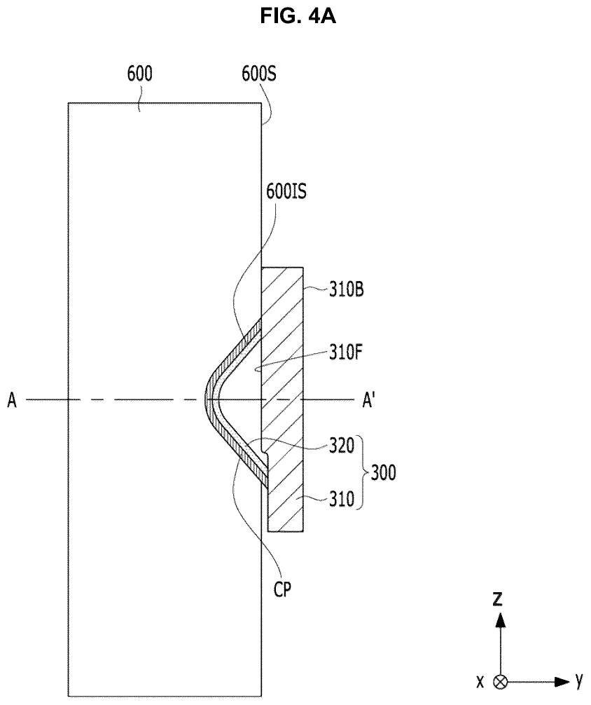

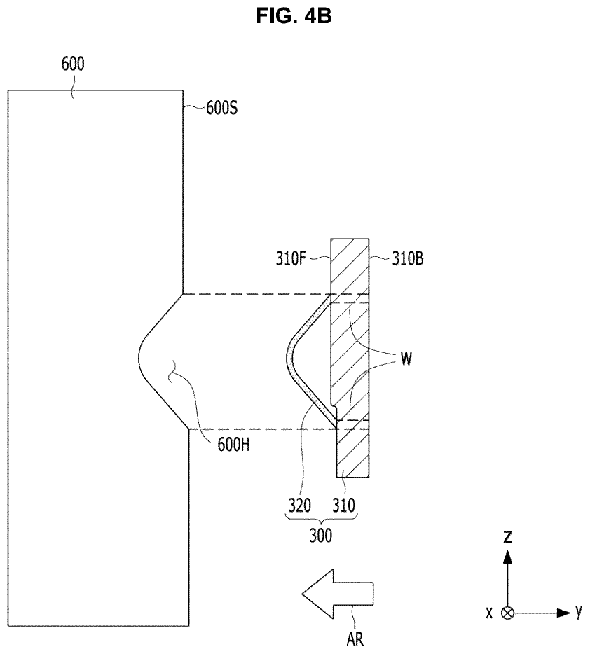

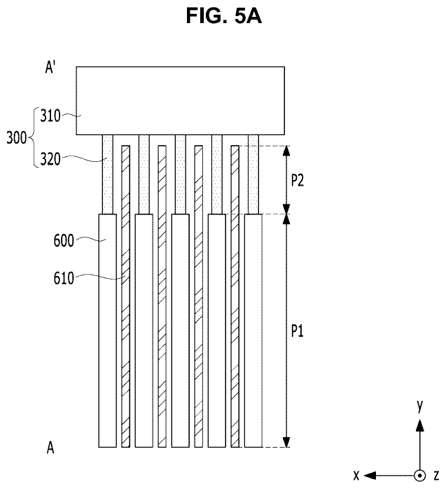

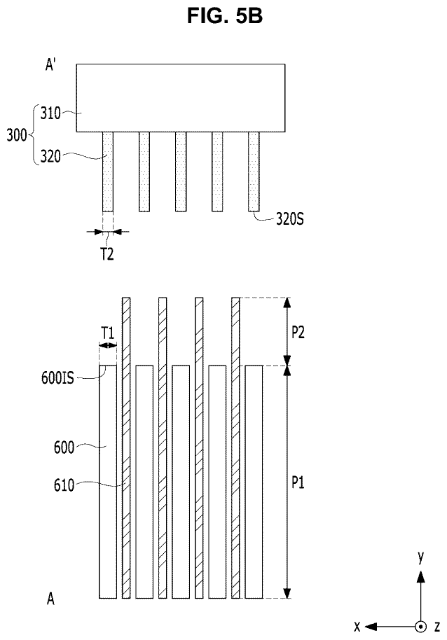

FIG. 2 is an overall exploded perspective view of separators 600 and a cell monitoring connector 300 according to an exemplary embodiment of the present disclosure. FIG. 3 is a partially exploded perspective view of the separators 600 and the cell monitoring connector 300 according to the exemplary embodiment of the present disclosure. FIG. 4A and FIG. 4B are, respectively, a partially coupled front view and an exploded front view of the separators 600 and the cell monitoring connector 300 shown in FIG. 3. FIG. 5A and FIG. 5B are, respectively, a coupled cross-sectional view and an exploded cross-sectional view taken along line A-A′ in FIG. 4A.

For convenience of description, among the components of the fuel cell, only the separators 600, to which the cell monitoring connector 300 is connected, are illustrated in FIG. 2, FIG. 3, FIG. 4 and FIG. 5B. Although four separators 600 are illustrated by way of example in FIGS. 3, 5A, and 5B, the following description applies to all of the separators 600.

Since the plurality of unit cells is stacked in the first direction, the plurality of separators 600 included in each of the unit cells is also spaced from each other in the first direction. Here, the separators 600 correspond to the separators 242 and 244 shown in FIG. 1.

According to the exemplary embodiment of the present disclosure, the cell monitoring connector 300 may be mounted to the separators 600 of the fuel cell in the second direction intersecting the first direction. As shown in FIG. 2, the entirety of the cell monitoring connector 300 may be mounted to all of the separators 600.

Hereinafter, the configurations of the separators 600 and the cell monitoring connector 300 coupled thereto will be described.

Each of the separators 600 includes an external side surface 600S in which a concave recess 600H (hereinafter referred to as a “female-type connection portion”) is formed. That is, the female-type connection portion 600H may be formed in the external side surface 600S of each of the separators 600 that faces the cell monitoring connector 300, among the external side surfaces of each of the separators 600.

The cell monitoring connector 300 may include a housing 310 and male-type connection portions (or cell sensing terminals) 320.

The housing 310 may include a front surface 310F and a rear surface 310B. The front surface 310F corresponds to a surface on which the male-type connection portion 320 is disposed, and the rear surface 310B corresponds to a surface formed opposite to the front surface 310F in the second direction.

The male-type connection portion 320 may protrude convexly from the front surface 310F of the housing 310 to mate with the female-type connection portion 600H. In the present way, the male-type connection portion 320 may come into surface-contact with an external side surface 600IS of the separator 600 within the female-type connection portion 600H. That is, the male-type connection portion 320 may not be disposed between the separators 600, and an external surface 320S of the male-type connection portion 320 may come into surface-contact with the external side surface 600IS of the separator 600.

Therefore, according to the exemplary embodiment of the present disclosure, the male-type connection portion 320 and the separator 600 do not overlap each other in the first direction.

When the housing 310 is moved in the second direction indicated by the arrow AR in FIG. 4B, the male-type connection portion 320 may be locked and primarily fixed in a state of being fitted to the female-type connection portion 600H by the spring force of the male-type connection portion 320. For this, the male-type connection portion 320 may be implemented by a material having elasticity.

According to the exemplary embodiment of the present disclosure, as shown in FIG. 5B, the external side surface 600IS of the separator 600, which makes surface-contact with the male-type connection portion 320, has a first thickness T1 in the first direction. The external surface 320S of the male-type connection portion 320, which makes surface-contact with the external side surface 600IS of the separator 600S, has a second thickness T2 in the first direction.

According to the exemplary embodiment of the present disclosure, a portion at which the external side surface 600IS including the first thickness T1 and the external surface 320S of the male-type connection portion 310 including the second thickness T2 overlap each other in the second direction may have an overlapping thickness T3 in the first direction, and the overlapping thickness may be greater than or equal to half the first or second thickness T1 or T2. However, the exemplary embodiments are not limited thereto. The reason for this is that a cell voltage is more accurately detected when surface-contact is made in a predetermined area between the external surface 320S and the external side surface 600IS.

Furthermore, referring to FIG. 4A, the external side surface 600IS within the female-type connection portion 600H of the separator 600, which makes surface-contact with the external surface 320S of the male-type connection portion 320, may include a uniform thickness, and the external surface 320S of the male-type connection portion 320, which makes surface-contact with the external side surface 600IS of the separator 600, may have a uniform thickness. That is, each of the first thickness T1 and the second thickness T2 may be uniform in the first direction. If any one of the first and second thicknesses T1 and T2 is not uniform, the area of a contact portion CP between the external surface 320S and the external side surface 600IS may decrease. Therefore, according to the exemplary embodiment of the present disclosure, because the thicknesses T1 and T2 are uniform, the area of the contact portion CP may be secured, as shown in Equation 1 below, thus making it possible for the cell monitoring connector 300 to more accurately detect the state of the unit cell.

TA=T1×L [Equation 1]

Here, TA represents the contact area between the external surface 320S of the male-type connection portion 320 and the external side surface 600IS of the separator 600, T1 represents the thickness of the external side surface 600IS of the separator 600, and L represents the contact length between the external surface 320S and the external side surface 600IS.

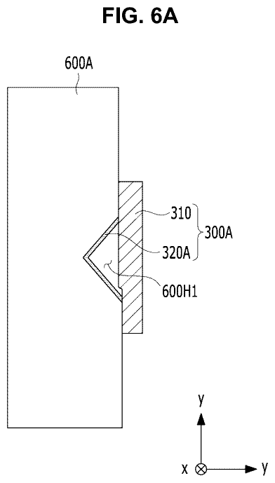

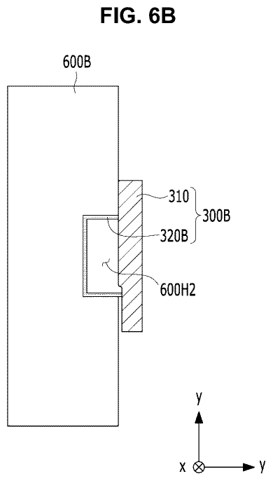

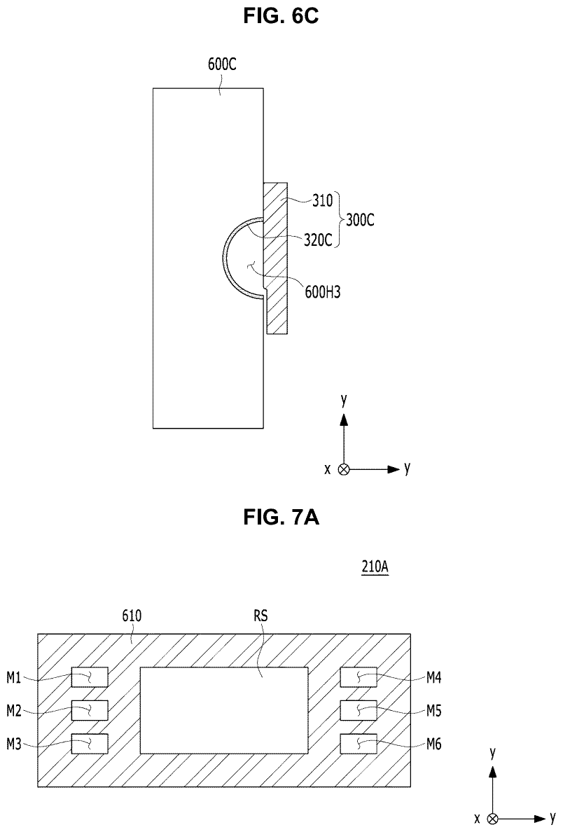

According to an exemplary embodiment of the present disclosure, as shown in FIG. 6A, a female-type connection portion 600H1 of a separator 600A may have a V-shape. In the instant case, a male-type connection portion 320A of a cell monitoring connector 300A also includes a V-shape, which is identical to the shape of the female-type connection portion 600H1.

According to another exemplary embodiment of the present disclosure, as shown in FIG. 6B, a female-type connection portion 600H2 of a separator 600B may have a rectangular shape. In the instant case, a male-type connection portion 320B of a cell monitoring connector 300B also has a rectangular shape, which is identical to the shape of the female-type connection portion 600H2.

According to various exemplary embodiments of the present disclosure, as shown in FIG. 6C, a female-type connection portion 600H3 of a separator 600C may have an arc shape. In the instant case, a male-type connection portion 320C of a cell monitoring connector 300C also includes an arc shape, which is identical to the shape of the female-type connection portion 600H3.

The shapes of the female-type connection portion 600H and the male-type connection portion 320 shown in FIG. 6A, FIG. 6B, and FIG. 6C are given by way of example, and the exemplary embodiments are not limited thereto. That is, the female-type connection portion 600H and the male-type connection portion 320 may have various cross-sectional shapes, when a sufficient contact area is secured therebetween and surface-contact with therebetween is stably maintained.

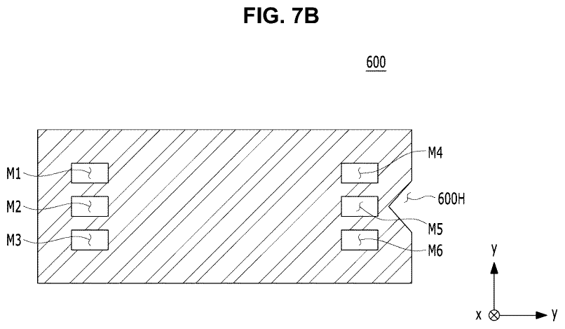

FIG. 7A is a front view of an exemplary embodiment 210A of the membrane electrode assembly, and FIG. 7B is a front view of an exemplary embodiment of the separator. Here, the membrane electrode assembly 210A corresponds to an exemplary embodiment of the membrane electrode assembly 210 shown in FIG. 1.

Referring to FIG. 7A and FIG. 7B, each of the membrane electrode assembly 210A and the separator 600 may include manifolds M1, M2, M3, M4, M5 and M6 formed in the same shape and at the same position as the manifolds of the end plate 110A. Here, the manifolds M1, M2, M3, M4, M5 and M6 may include inlet manifolds M1, M2, and M4 and outlet manifolds M3, M5, and M6. Hydrogen and oxygen, which are reactant gases necessary in the membrane electrode assembly 210A, may be introduced from the outside thereof into the cell stack 122 through the inlet manifolds M1 and M4. Gas or liquid, in which the reactant gases humidified and supplied to the cell and condensed water generated in the cell are combined, may be discharged to the outside of the fuel cell through the outlet manifolds M3 and M6. Furthermore, a cooling medium may flow from the outside thereof into the cell stack 122 through the inlet manifold M2 and may flow outside through the outlet manifold M5. In the present way, the manifolds M1, M2, M3, M4, M5 and M6 allow the fluid to flow in and out of the membrane electrode assembly 210A.

In the instant case, the membrane electrode assembly 210A included in the unit cell may further include a reaction surface RS and a sub-gasket 610.

The reaction surface RS is a portion disposed at the center portion of the membrane electrode assembly 210A, and the sub-gasket 610 may be disposed around the reaction surface RS.

The sub-gasket 610 corresponds to an exemplary embodiment of the sub-gasket 238 shown in FIG. 1.

According to the exemplary embodiment of the present disclosure, the sub-gasket 610 may include a film-type insulating material (e.g., polyethylene naphthalate (PEN) film). However, the exemplary embodiments are not limited thereto.

A PEN film has a rigid molecular chain structure, which is one of important properties of a polyester film, and therefore, has excellent tensile strength, impact strength, and fracture strength and has an appropriate elongation ratio while having a relatively small thickness, compared to a PET film. Furthermore, a PEN film has excellent thermal dimensional stability compared to a PET film, and has higher electrical insulation, dielectric constant, and dielectric breakdown voltage than a PET film. Furthermore, a PEN film has a very small amount of oligomer extracted from the film and exhibits excellent oil resistance, chemical resistance, hydrolysis resistance, gas barrier property, and radiation resistance. Accordingly, a PEN film has excellent mechanical, thermal, electrical and chemical properties.

Referring to FIG. 5A and FIG. 5B, the sub-gasket 610 is disposed between two neighboring separators (hereinafter referred to as “first and second separators”) among the plurality of separators, and the male-type connection portion 320 includes two male-type connection portions (hereinafter referred to as “first and second male-type connection portions”) that make surface-contact with the first and second separators, respectively.

The sub-gasket 610 may include a first portion P1 and a second portion P2.

The first portion P1 is a portion disposed between the first and second separators while being spaced from the first and second separators in the first direction.

The second portion P2 is a portion extending from the first portion P1 in the second direction toward the cell monitoring connector 300 and disposed between the first and second male-type connection portions 320 while being spaced from the first and second male-type connection portions 320 in the first direction.

Furthermore, according to the exemplary embodiment of the present disclosure, as shown in FIG. 7B, the female-type connection portion 600H may be disposed close to the fifth manifold M5. However, the exemplary embodiments are not limited thereto. That is, according to another exemplary embodiment of the present disclosure, the female-type connection portion 600H may be disposed close to the fourth or sixth manifold M4 or M6.

Alternatively, the female-type connection portion 600H may be formed near to the first, second, and third manifolds M1, M2, and M3 to mate with the male-type connection portion 320.

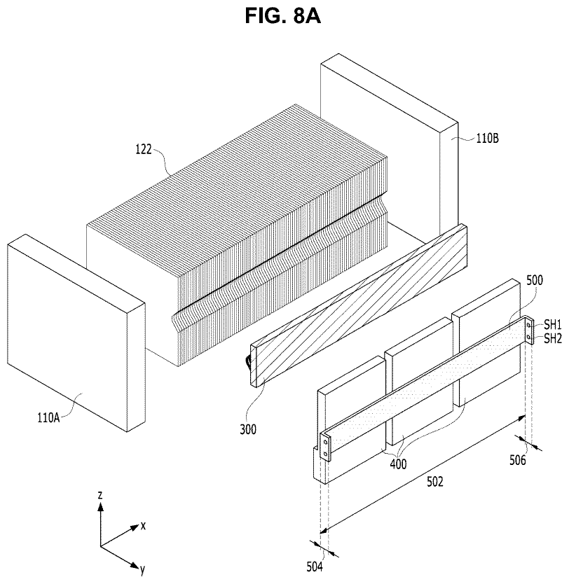

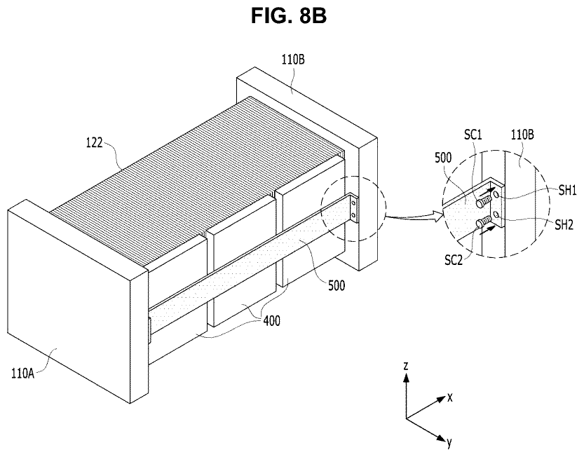

FIG. 8A is an exploded perspective view of a fuel cell apparatus according to another exemplary embodiment of the present disclosure, and FIG. 8B is a coupled perspective view of the fuel cell apparatus shown in FIG. 8A.

The fuel cell apparatus shown in FIG. 8A and FIG. 8B may include first and second end plates 110A and 110B, a cell stack 122, and a fixing frame 500.

The first and second end plates 110A and 110B and the cell stack 122 shown in FIG. 8A and FIG. 8B correspond to the first and second end plates 110A and 110B and the cell stack 122 shown in FIG. 1, respectively. Therefore, the same components are denoted by the same reference numerals, and duplicate descriptions thereof will be omitted.

As described above, the male-type connection portion 320 is primarily fixed to the female-type connection portion 600H by the spring force of the male-type connection portion 320. However, when the fuel cell apparatus moves, the male-type connection portion 320 may be separated from the female-type connection portion 600H. Therefore, according to the exemplary embodiment of the present disclosure, the fixing frame 500 is configured to secondarily fix and support the male-type connection portion 320 so that the male-type connection portion 320 is not separated from the female-type connection portion 600H.

Referring to FIGS. 4B, 8A, and 8B, the fixing frame 500 is disposed on the rear surface 310B of the housing 310 to support the housing 310.

According to the exemplary embodiment of the present disclosure, the fixing frame 500 may further include a support portion 502 and coupling portions 504 and 506.

The support portion 502 is disposed on the rear surface 310B of the housing 310. To prevent the male-type connection portion 320 from being separated from the female-type connection portion 600H, the support portion 502 may be disposed to overlap the rear surface 310B of the housing 310 in the second direction.

The coupling portions 504 and 506 may be formed at both end portions of the support portion 502 in the first direction and may be coupled to the end plates 110A and 110B. That is, the first coupling portion 504 may be formed at one end portion of the support portion 502 and may be coupled to the first end plate 110A, and the second coupling portion 506 may be formed at the other end portion of the support portion 502 and may be coupled to the second end plate 110B.

For example, the first and second coupling portions 504 and 506 may be screwed to the first and second end plates 110A and 110B, respectively. That is, the second coupling portion 506 may include a first through-hole SH1 through which a first screw SC1 is fastened and a second through-hole SH2 through which a second screw SC2 is fastened. The first screw SC1 may be fastened to the second end plate 110B through the first through-hole SH1, and the second screw SC2 may be fastened to the second end plate 110B through the second through-hole SH2. Similarly, the first coupling portion 504 may also include through-holes through which screws are fastened and may be coupled to the first end plate 110A by the screws.

Furthermore, the fuel cell apparatus may further include a control circuit 400. To determine the performance of the cell stack 122 and whether the cell stack 122 operates normally or abnormally, the voltage of each cell may be measured by connecting the separators 242 and 244 of each cell to the control circuit 400 via the cell monitoring connector (or fuel stack voltage monitor (FSVM)) 300 and wires. The control circuit 400 may be a circuit including a measuring device and an electronic control unit of operating the fuel cell in the vehicle. That is, the control circuit 400 is connected to the cell monitoring connector 300.

To the present end, for example, as shown in FIG. 4B, a wire W including an end portion connected to the male-type connection portion 320 and another end portion connected to the control circuit 400 may be disposed to penetrate the housing 310.

Alternatively, the male-type connection portion 320 and the control circuit 400 may be connected to each other in a board-to-board connection manner. The exemplary embodiments are not limited to any specific connection structure of the male-type connection portion 320 and the control circuit 400.

According to the exemplary embodiment of the present disclosure, as shown in FIGS. 8A and 8B, the control circuit 400 may be disposed between the rear surface 310B of the housing 310 and the fixing frame 500.

Hereinafter, a fuel cell apparatus according to a comparative example and the fuel cell apparatus according to the exemplary embodiment of the present disclosure will be compared and described.

An example of a fuel cell apparatus according to a comparative example is included in Korean Patent Registration No. 10-1337937, and the included comparative example and the exemplary embodiment of the present disclosure will be compared and described below.

In the case of the fuel cell apparatus according to the comparative example, “separator tabs” are formed on the separators, and a connector for measuring cell voltage is connected to the separator tabs to detect a cell voltage. When a plurality of unit cells is stacked, the separator tabs are aligned. As shown in FIG. 14 of Korean Patent Registration No. 10-1337937, the connector for measuring cell voltage is connected between the separator tabs to detect a cell voltage. However, as stack technology advances, narrow-pitch stacks are being developed, and accordingly, the wall of a connector for measuring cell voltage becomes thinner. This incurs problems such as increase in difficulty of injection molding of the connector for measuring cell voltage, difficulty in mounting the connector for measuring cell voltage to the separator tabs, and difficulty of alignment of the separator tabs during mass production of stacks. In the case of the comparative example, because the separators are formed as thin steel plates, the separators bend easily, thus deteriorating assemblability. Furthermore, because gaps in the housing, into which the separator tabs are inserted, are very narrow, if the connector for measuring cell voltage is twisted even slightly, mounting of the connector for measuring cell voltage is impossible. Therefore, overall assemblability is very poor.

In contrast, according to the exemplary embodiment of the present disclosure, the male-type connection portion 320 of the cell monitoring connector 300 makes surface-contact with the external side surface 600IS of the separator 600, rather than being inserted between separator tabs. That is, in the comparative example, the separator tab is formed on the external side of the separator, whereas in the exemplary embodiment of the present disclosure, a recess is formed as the female-type connection portion 600H in the external side of the separator 600. Accordingly, the exemplary embodiment of the present disclosure may improve the assemblability of a narrow-pitch stack.

Furthermore, in the case of the comparative example, a connection terminal of the connector for measuring cell voltage, which is coupled to the separator tab, includes a complicated configuration, such as a wire gripper (or barrel) configured to fix the wire.

In contrast, in the case of the exemplary embodiment of the present disclosure, the male-type connection portion 320, which corresponds to the connection terminal of the comparative example, protrudes from the housing 310 and comes into surface-contact with the external side surface 600IS of the separator 600. That is, the exemplary embodiment has a simple connection structure.

Furthermore, in the case of the comparative example, after the connector for measuring cell voltage is fixed to the separator tab, connector position assurance (CPA) is used to prevent separation of the connector for measuring cell voltage. In contrast, in the case of the exemplary embodiment of the present disclosure, separation of the male-type connection portion 320 from the female-type connection portion 600H is prevented by the spring force of the male-type connection portion 320 and the fixing frame 500.

Furthermore, in the case of the comparative example, terminal position assurance (TPA) is required to guide the connection terminal to a correct position when assembling the same to the housing and to increase terminal holding force.

In contrast, in the case of the exemplary embodiment of the present disclosure, since the male-type connection portion 320 connected to the wire W is connected to the external side surface 600IS of the separator 600, the TPA used in the comparative example is not required.

Furthermore, in the case of the comparative example, the separators are grouped into a predetermined number of separator groups, and a plurality of connectors for measuring cell voltage is individually mounted to the separator groups. For example, if the number of separators is 200, each of the connectors for measuring cell voltage is mounted to a separator group including ten separators. In other words, a total of twenty connectors for measuring cell voltage is sequentially mounted to the separator groups.

In contrast, in the case of the exemplary embodiment of the present disclosure, as shown in FIG. 2, the male-type connection portions 320 may be simultaneously mounted in the plurality of female-type connection portions 600H of all of the separators 600.

As described above, in the case of the exemplary embodiment of the present disclosure, since the cell monitoring connector has a simple configuration, an assembly process may be simplified, production costs may be reduced, and worker convenience may be improved, compared to the comparative example. For example, in the comparative example, it takes about 10 to 30 minutes to connect the connectors for measuring cell voltage to the separators, whereas in the exemplary embodiment of the present disclosure, it takes about 1 to 2 minutes to connect the cell monitoring connector to the external side surfaces 600IS of the separators. That is, the exemplary embodiment of the present disclosure may greatly reduce an assembly process time.

Furthermore, in the case of the exemplary embodiment of the present disclosure, since the sub-gasket 610 including an insulating property is disposed between the male-type connection portions 320, excellent electrical insulation may be obtained.

As is apparent from the above description, according to the fuel cell apparatus according to the exemplary embodiment of the present disclosure, because the cell monitoring connector has a simple configuration, an assembly process may be simplified, production costs may be reduced, and worker convenience may be improved.

However, the effects achievable through the present disclosure are not limited to the above-mentioned effects, and other effects not mentioned herein will be clearly understood by those skilled in the art from the above description.

The above-described various embodiments may be combined with each other without departing from the scope of the present disclosure unless they are incompatible with each other.

Furthermore, for any element or process which is not described in detail in any of the various exemplary embodiments of the present disclosure, reference may be made to the description of an element or a process having the same reference numeral in another exemplary embodiment of the present disclosure, unless otherwise specified.

Furthermore, the term related to a control device such as “controller”, “control apparatus”, “control unit”, “control device”, “control module”, “control circuit”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

In various exemplary embodiments of the present disclosure, each operation described above may be performed by a control device, and the control device may be configured by a plurality of control devices, or an integrated single control device.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A fuel cell apparatus, comprising:
a fuel cell including a cell stack including a plurality of unit cells stacked in a first direction; and
a cell monitoring connector mounted to the fuel cell in a second direction intersecting the first direction,
wherein the fuel cell includes a plurality of separators included in each of the unit cells and spaced from each other in the first direction,
wherein each of the separators includes an external side surface in which a first connection portion is concavely formed, and
wherein the cell monitoring connector includes:
a housing; and
a second connection portion convexly protruding from the housing to mate with the first connection portion and to make surface-contact with the external side surface of each of the separators within the first connection portion.

2. The fuel cell apparatus of claim 1, wherein the second connection portion is locked in a state of being fitted to the first connection portion by a spring force of the second connection portion having an elasticity.

3. The fuel cell apparatus of claim 1, wherein the housing includes:
a front surface on which the second connection portion is disposed; and
a rear surface formed opposite to the front surface in the second direction, and
wherein the fuel cell further includes end plates disposed at respective end portions of the cell stack.

4. The fuel cell apparatus of claim 3, further including:
a fixing frame disposed on the rear surface of the housing and supporting the housing,
wherein the fixing frame includes:
a support portion disposed on the rear surface of the housing; and
coupling portions formed at first and second end portions of the support portion in the first direction to be coupled to the end plates.

5. The fuel cell apparatus of claim 4, further including:
a control circuit connected to the cell monitoring connector,
wherein the control circuit is disposed between the rear surface of the housing and the fixing frame.

6. The fuel cell apparatus of claim 1,
wherein each of the unit cells includes a membrane electrode assembly, and
wherein the membrane electrode assembly includes:
a reaction surface disposed at a center portion thereof; and
a sub-gasket disposed around the reaction surface.

7. The fuel cell apparatus of claim 6,
wherein the sub-gasket is disposed between first and second separators adjacent to each other among the plurality of separators,
wherein the second connection portion includes one and another second connection portions formed to make surface-contact with the first and second separators, respectively, and
wherein the sub-gasket includes:
a first portion disposed between the first and second separators while being spaced from the first and second separators in the first direction; and
a second portion extending from the first portion in the second direction and disposed between the one and another second connection portions while being spaced from the one and another second connection portions in the first direction.

8. The fuel cell apparatus of claim 6, wherein the sub-gasket includes a film-type insulating material.

9. The fuel cell apparatus of claim 6, wherein the sub-gasket includes a polyethylene naphthalate (PEN) film.

10. The fuel cell apparatus of claim 1,
wherein the external side surface of each of the separators making surface-contact with the second connection portion has a first thickness in the first direction, and
wherein the second connection portion making surface-contact with the external side surface of each of the separators has a second thickness in the first direction.

11. The fuel cell apparatus of claim 10,
wherein a portion at which the external side surface having the first thickness and the second connection portion having the second thickness overlap each other in the second direction includes an overlapping thickness in the first direction, and
wherein the overlapping thickness is greater than or equal to half the first or second thickness.

12. The fuel cell apparatus of claim 10,
wherein the external side surface within the first connection portion of each of the separators making surface-contact with the second connection portion has a uniform thickness, and
wherein the second connection portion making surface-contact with the external side surface of each of the separators has a uniform thickness.

13. The fuel cell apparatus of claim 1, wherein the first connection portion includes a V-shape, a rectangular shape, or an arc shape.

14. The fuel cell apparatus of claim 1, wherein the second connection portion and each of the separators do not overlap each other in the first direction.
